(19) United States
(12) Patent Application Publication
(10) Pub. No.: US 2010/0097243 A1
(43) Pub. Date: Apr. 22, 2010

(54) MULTIFUNCTION MOUSE

(75) Inventor: Zi-Yu Zhan, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO.,LTD., Shenzhen City (CN); HON HAI PRECISION INDUSTRY CO., LTD., Tu-Cheng (TW)

(21) Appl. No.: 12/268,424

(22) Filed: Nov. 10, 2008

(30) Foreign Application Priority Data
Oct. 16, 2008 (CN) 200810304946.1

(51) Int. Cl. H03K 17/94

(52) U.S. Cl. 341/20

(57) ABSTRACT

A multifunction mouse includes a main body, a divider, and a cover. The main body includes a front portion as a finger operating portion, a rear portion as a palm holding portion. The divider is configured for dividing the main body. The divider and the cover are positioned in the palm holding portion. The divider is located between the palm holding portion and the cover. A receiving cavity is defined between the cover and the divider to receive health care materials. A number of through holes is defined in the cover.

### BACKGROUND

1. Technical Field

The present disclosure relates to computer pointing devices and, particularly, to a multifunction computer mouse.

2. Description of the Related Art

Computer pointing devices, commonly known as “mouse,” are made large enough for comfortably gripping and manipulating by hand. However, internal structure of a computer mouse is very simple, and since the mouse is usually not multipurpose, there is a lot of unused space available in the mouse.

What is desired, therefore, is to provide a multifunction/multipurpose mouse.

### BRIEF DESCRIPTION OF THE DRAWINGS

FIG. 1 is an exploded view of an exemplary embodiment of a multifunction mouse.

FIG. 2 is an assembled, partial sectional view of an exemplary embodiment of the multifunction mouse of FIG. 1.

FIG. 3 is a top plane of the multifunction mouse of FIG. 2.

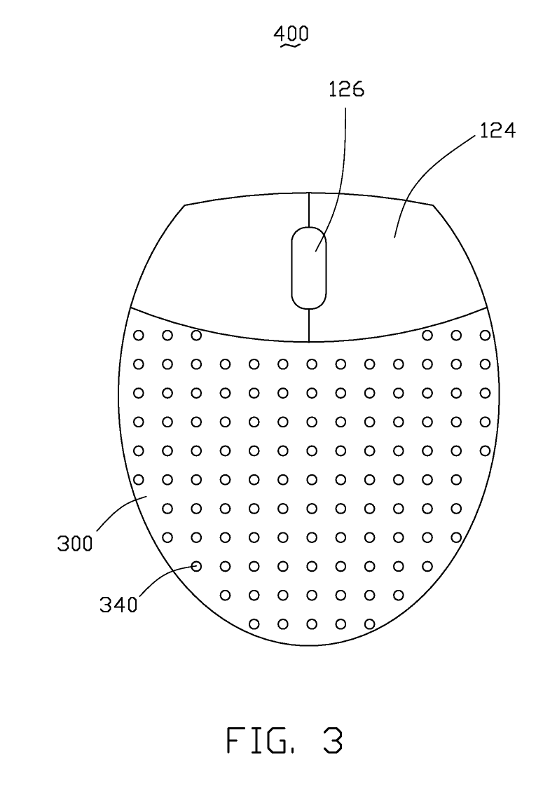

### DETAILED DESCRIPTION

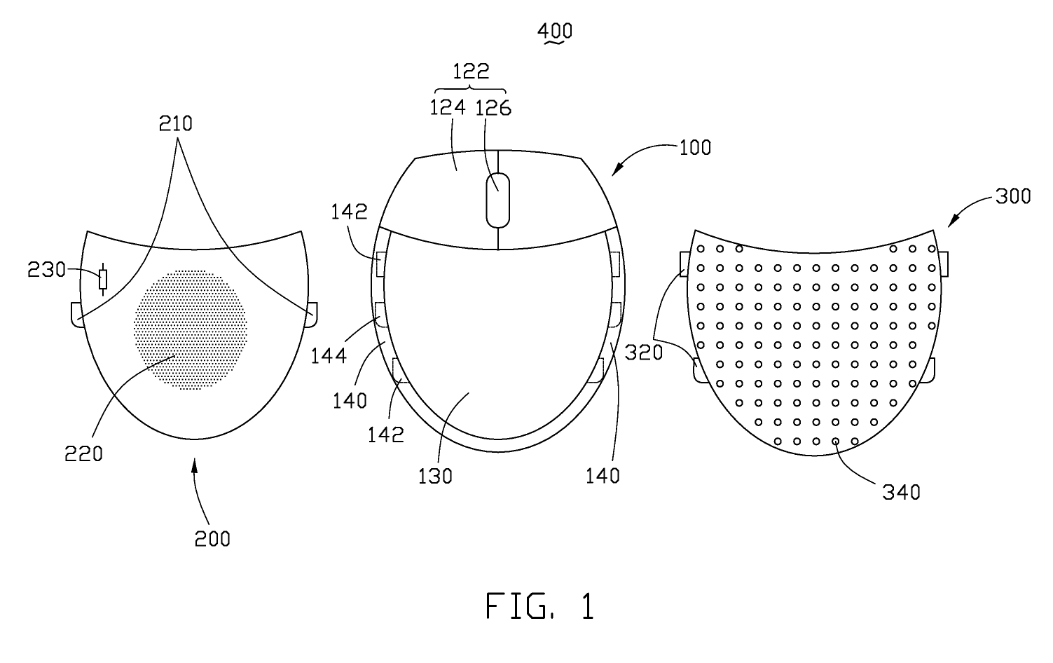

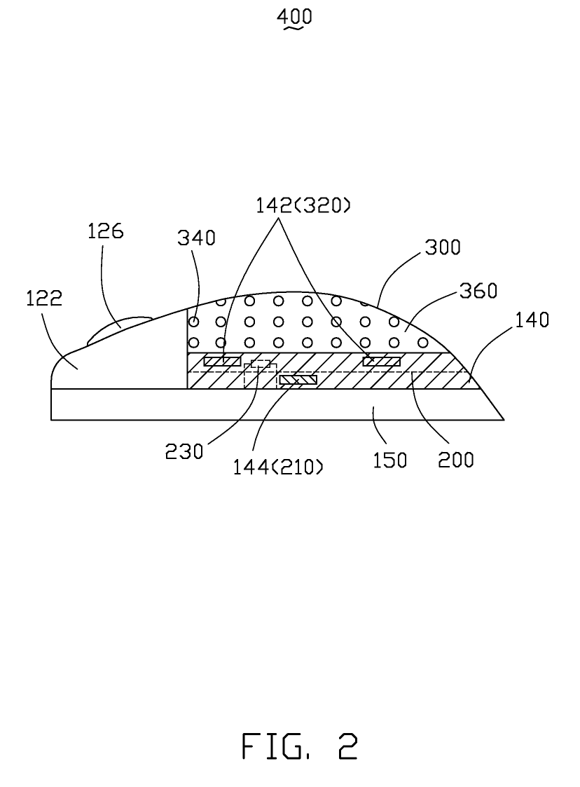

Referring to FIGS. 1 and 2, an exemplary embodiment of a multifunction mouse 400 includes a main body 100, a divider 200, and a cover 300. A front part of the main body 100 is used as a finger operating portion 122 that includes two buttons 124 and a scroll wheel 126. A rear part of the main body 100 is used as a raised palm holding portion 130. The cover 300 is arched corresponding to the shape of the palm holding portion 130.

A pair of slots 142 are defined in each of two inner sidewalls 140 of the palm holding portion 130. A slot 144 is defined in each of two inner sidewalls 140 and located below the pair of slots 142.

The divider 200 is configured for dividing the interior of the main body 100 into two compartments. One compartment to receive electrical elements such as a circuit board of the mouse 400 and the other compartment for receiving components related to other functions selected for the mouse 400. The shape of the divider 200 is configured to contact the sidewalls 140 on all sides for a tight fit. Two protrusions 210 extend from two sidewalls of the divider 200 to latch with the slots 144 to position the divider 200 on the sidewalls 140 of the palm holding portion 130.

A pair of blocks 320 extends from each of two sidewalls of the cover 300 to latch with the pairs of slots 142 to position the cover 300 on the sidewalls 140 of the palm holding portion 130. A receiving cavity 360 is defined by the cover 300, the divider 200, and the sidewalls 140 to receive, for example, healthful natural or man-made materials such as essential and/or aromatic herbs and oils designated as materials 220. A plurality of through holes 340 is defined in the cover 300 to communicate and the receiving cavity 360 with outside of the mouse 400. The materials 220 may have the qualities of being moisture absorbent and capable of absorbing sweat from the hand of a user, and providing other benefits to users such as giving them a refreshing feeling from their odor. In this embodiment the materials 220 are essential herbs that are placed dry into the receiving cavity.

Referring to FIG. 2, in assembly, the protrusion 210 of the divider 200 is latched with the slots 144 of the sidewalls 140 of the main body 100 to position the divider 200 on the main body 100. The materials 220 are put on the divider 200. The pairs of blocks 320 of the cover 300 are latched with the corresponding pairs of slots 142 of the sidewalls 140 of the main body 100 to position the cover 300 on the main body 100. When using the mouse 400, the material 220 can emit a refreshing scent via the plurality of through holes 340.

In the illustrated embodiments, if the materials 220 are oils, then a heating element 230, such as a resistor connected between a power terminal and a ground terminal of the circuit board, and positioned against the divider 200 to heat the divider 200 may be provided, so that the oils may more easily give off beneficial vapors. The divider 200 may be made of insulating material to keep heat produced by the heating from the circuit board, and sealed with the sidewalls of the mouse 400 to prevent the oil from getting on the circuit board. When using oil for the materials 220, the oil may be introduced into the receiving cavity 360 via the through holes 340 from outside of the mouse 400. Additionally, a bottom portion 150 can be removably attached to mouse 400 to allow access to the compartment containing the circuit board if needed.

It is to be understood, however, that even though numerous characteristics and advantages of the disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A multifunction mouse comprising:
a main body comprising a front portion as a finger operating portion, and a rear portion as a palm holding portion;
a divider configured for dividing the main body;
a cover for resting of a user's palm thereon and defining a plurality of through holes;
wherein the cover are positioned on the palm holding portion, a receiving cavity is defined between the cover and the divider to receive materials, the through holes communicate the receiving cavity and outside to emit scene of the material.

2. The multifunction mouse of claim 1, wherein a shape of the divider is configured to contact the inner sidewalls of the main body on all sides for a tight fit.

3. The multifunction mouse of claim 2, wherein a first pair of slots is defined in each of two opposite sidewalls of the palm holding portion, a pair of blocks extends from each of two sidewalls of the cover and correspondingly latched with the first pair of slots to position the cover on the sidewalls of the palm holding portion.

4. The multifunction mouse of claim 3, wherein a second slot is defined in each of the two opposite sidewalls of the palm holding portion and located below the first pair of slots, a protrusion extends from each of two sidewalls of the divider and corresponding to the second slot to latch with the second slot to position the divider on the sidewalls of the palm holding portion.

5. The multifunction mouse of claim 1, wherein the materials are essential herbs that are placed into the receiving cavity.

6. The multifunction mouse of claim 1, wherein the materials are scented oils.

7. The multifunction mouse of claim 7, wherein a heating element is position against the divider.
